(19) United States
(12) Patent Application Publication
(10) Pub. No.: US 2026/0050728 A1
(43) Pub. Date: Feb. 19, 2026

(54) LAYOUT DESIGN METHOD

(71) Applicant: United Microelectronics Corp., Hsinchu (TW)

(72) Inventors: Chien Heng Liu, Pingtung County (TW); Chia-Wei Huang, Kaohsiung City (TW); Yung-Feng Cheng, Kaohsiung City (TW)

(73) Assignee: United Microelectronics Corp., Hsinchu (TW)

(21) Appl. No.: 18/895,315

(22) Filed: Sep. 24, 2024

(30) Foreign Application Priority Data
Aug. 19, 2024 (TW) 113131079

(51) Int. Cl. G06F 30/392

(52) U.S. Cl. CPC G06F 30/392

(57) ABSTRACT

A layout design method including the following steps is provided. A dense pattern area, a loose pattern area, and a boundary of a layout layer are identified. The loose pattern area is adjacent to the dense pattern area. The boundary is located between the dense pattern area and the loose pattern area. The dense pattern area comprises a plurality of polygons, and the loose pattern area comprises at least one polygon. A step of increasing a pitch and a line width is performed on N polygons of the plurality of polygons of the dense pattern area closest to the boundary, wherein the N is an integer. The step of increasing the pitch and the line width is limited to not affecting a first connection between the layout layer and a lower layer, nor a second connection between the layout layer and an upper layer.

### CROSS-REFERENCE TO RELATED APPLICATION

This application claims the priority benefit of Taiwan application serial no. 113131079, filed on Aug. 19, 2024. The entirety of the above-mentioned patent application is hereby incorporated by reference herein and made a part of this specification.

### BACKGROUND

### Technical Field

The disclosure relates to a semiconductor layout, and particularly relates to a layout design method.

### Description of Related Art

Due to the characteristics of light itself, such as diffraction, interference, and other semiconductor process effects, as the size of the pattern on the mask layout becomes increasingly smaller, more and more obvious pattern differences will occur when transferred to the wafer, such as size changes, shape changes, etc. In particular, in boundary areas with different pattern densities, or boundary areas with changing pitch, after the photoresist is exposed and developed, abnormal phenomena such as pattern bridge or pattern broken often occur, which may cause problems during subsequent etching; moreover, at the boundary with different pattern densities or at the boundary where the pitch changes, there will be pattern shift lithography errors, which will lead to the problem of connection failure with the upper and lower layers.

For example, in the gate layer, its plurality of dense gate patterns and an isolation structure, such as a shallow trench isolation (STI), form obvious differences in pattern density. After the photolithography process, the exposed gate line width and pitch will become increasingly smaller closer to the gate pattern area and the isolation structure area. Therefore, physical connection failure such as misalignment between the layer and its upper and lower layers may occur, or there will be a problem of electrical connection between its upper and lower layers thereof.

### SUMMARY

The disclosure provides a layout design method, which solves abnormal phenomena such as pattern shift, pattern bridge, or pattern broken due to optical factors, so that the physical and electrical connections between a layout layer and its upper and lower layers are maintained in a good state.

An embodiment of the disclosure provides a layout design method, including: identifying a dense pattern area, a loose pattern area, and a boundary of a layout layer, wherein: the loose pattern area is adjacent to the dense pattern area, the boundary is located between the dense pattern area and the loose pattern area, the dense pattern area includes a plurality of polygons, and the loose pattern area includes at least one polygon; and performing a step of increasing a pitch on N polygons of the plurality of polygons of the dense pattern area closest to the boundary, wherein n is an integer, and the step of increasing the pitch is limited to not affecting a first connection between the layout layer and a lower layer, nor a second connection between the layout layer and an upper layer.

In some embodiments, the step of increasing the pitch includes gradually increasing the pitch of the N polygons toward the boundary.

In some embodiments, gradually increasing the pitch of the N polygons toward the boundary includes: gradually increasing the pitch of the N polygons toward the boundary in arithmetic progression; or gradually increasing the pitch of the N polygons toward the boundary in geometric progression.

In some embodiments, N ranges from 1 to 7.

In some embodiments, the step of increasing the pitch includes increasing the pitch of the N polygons by 0.1% to 20%.

In some embodiments, the layout layer includes a gate layer, a contact layer, or a metal wire layer of a back-end of line process.

In some embodiments, the plurality of polygons of the dense pattern area include gates, contacts, or metal wires of a back-end of line process.

In some embodiments, a width of the at least one polygon of the loose pattern area is greater than a width of the plurality of polygons of the dense pattern area.

In some embodiments, the loose pattern area includes an isolation structure area, and the isolation structure area includes a shallow trench isolation (STI).

In some embodiments, the first connection includes a first electrical connection or a first physical connection, and the second connection includes a second electrical connection or a second physical connection.

An embodiment of the disclosure provides a layout design method, including: identifying a dense pattern area, a loose pattern area, and a boundary of a layout layer, wherein: the loose pattern area is adjacent to the dense pattern area, the boundary is located between the dense pattern area and the loose pattern area, the dense pattern area includes a plurality of polygons, and the loose pattern area includes at least one polygon; and performing a step of increasing a pitch and a line width on N polygons of the plurality of polygons of the dense pattern area closest to the boundary, wherein n is an integer, and the step of increasing the pitch and the line width is limited to not affecting a first connection between the layout layer and a lower layer, nor a second connection between the layout layer and an upper layer.

In some embodiments, the step of increasing the pitch and the line width includes gradually increasing the pitch and the line width of the N polygons toward the boundary.

In some embodiments, gradually increasing the pitch and the line width of the N polygons toward the boundary includes: gradually increasing the pitch of the N polygons toward the boundary in arithmetic progression, or gradually increasing the pitch of the N polygons toward the boundary in geometric progression; and gradually increasing the line width of the N polygons toward the boundary in arithmetic progression, or gradually increasing the line width of the N polygons toward the boundary in geometric progression.

In some embodiments, N ranges from 1 to 7.

In some embodiments, the step of increasing the pitch includes: increasing the pitch of the N polygons by 0.1% to 20%; and increasing the line width of the N polygons by 0.1% to 20%.

In some embodiments, the layout layer includes a gate layer, a contact layer, or a metal wire layer of a back-end of line process.

In some embodiments, the plurality of polygons of the dense pattern area include gates, contacts, or metal wires of a back-end of line process.

In some embodiments, a width of the at least one polygon of the loose pattern area is greater than a width of the plurality of polygons of the dense pattern area.

In some embodiments, the loose pattern area includes an isolation structure area, and the isolation structure area includes a shallow trench isolation (STI).

In some embodiments, the first connection includes a first electrical connection or a first physical connection, and the second connection includes a second electrical connection or a second physical connection.

Based on the above, the disclosure provides a layout design method, which involves the step of increasing the pitch and the line width of the N polygons closest to the boundary between the dense pattern area and the loose pattern area of the layout layer to improve the resolution of patterns at boundary with different pattern densities so as to make the exposed pattern closer to the original position and shape and solve abnormal phenomena such as pattern shift, pattern bridge, or pattern broken due to optical factors, so that the connections between the layout layer and its upper and lower layers are maintained in a good state.

In order to make the above-mentioned features and advantages of the disclosure clearer and easier to understand, the following embodiments are given and described in details with accompanying drawings as follows.

### BRIEF DESCRIPTION OF THE DRAWINGS

FIG. 1 is a schematic layout diagram before adjustment and correction according to an embodiment of the disclosure.

FIG. 2 is a schematic layout diagram after adjustment and correction according to an embodiment of the disclosure.

FIG. 3 is a schematic layout diagram after adjustment and correction according to another embodiment of the disclosure.

### DESCRIPTION OF THE EMBODIMENTS

The disclosure will be described more comprehensively below with reference to the drawings of the embodiment. However, the disclosure may also be implemented in various forms, and shall not be limited to the embodiments described herein. The sizes and distances of the polygons in the drawings are drawn for visual clarity and are not the original sizes and distances. The same or similar reference numbers indicate the same or similar elements, and the following paragraphs will not repeat them one by one.

As used herein, “connection” may refer to physical and/or electrical connections, and “electrical connection” or “coupling” may refer to the presence of other elements between two elements.

The terms “about”, “approximately” or “substantially” as used herein include values as mentioned and average values of specific values capable of being determined by those of ordinary skill in the art within an acceptable deviation range, and measurement discussed and a specific number (i.e., limitation to a measurement system) of measurement-related errors are considered. For example, “about” may be expressed within one or more standard deviations of the value, or within +30%, +20%, +10%, +5%. Furthermore, the terms “about”, “approximately” or “substantially” used herein may select a more acceptable deviation range or standard deviation according to optical properties, etching properties or other properties, and may not to apply one standard deviation to all the properties.

The wording used herein is used only to illustrate exemplary embodiments, but not intended to limit the disclosure. In this case, a singular form includes a plural form unless otherwise explained in the context.

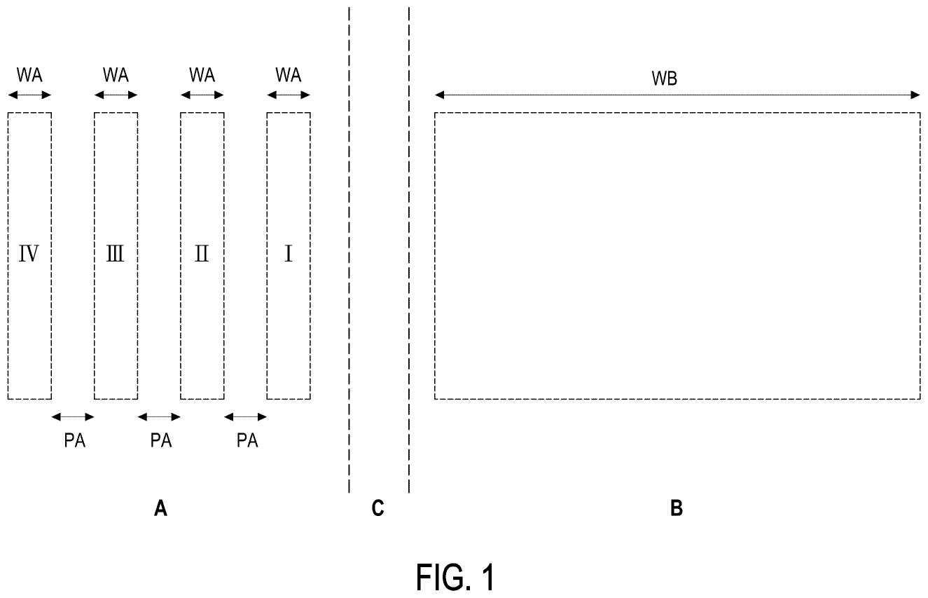

First, refer to FIG. 1, which is a schematic layout diagram before adjustment and correction according to an embodiment of the disclosure.

The layout design method of the disclosure adjusts and corrects the pattern of the layout layer. The layout layer may be used in the front end of line (FEOL) and middle of line (MOL) processes in the semiconductor process. The packaging and testing performed by packaging and testing factories may be used at all levels of the back-end of line (BEOL) process. As long as the layer is deformed or displaced due to changes in pattern density when the mask pattern is transferred to the photoresist on the wafer, the layout design method of the disclosure may be used for adjustment and correction; in particular, the gate layer, the contact layer, or the metal wire layer of the back-end of line process, which are the most critical in the semiconductor manufacturing process and have the densest patterns, may be adjusted and corrected using the layout design method of the disclosure.

The layout at the layout layer includes a dense pattern area A, a loose pattern area B, and a boundary C. The loose pattern area B is adjacent to the dense pattern area A, and the boundary C is located between the dense pattern area A and the loose pattern area B.

Following the above, the dense pattern area A includes a plurality of polygons, such as the four polygons shown in FIG. 1, including a first polygon I, a second polygon II, a third polygon III, and a fourth polygon IV. However, the number of the plurality of polygons of the dense pattern area A is not limited thereto, and may be less than 4 or more than 4.

Based on the above, the plurality of polygons of the dense pattern area A have line widths and pitches, and each line width and pitch may be the same or different; in order to make the drawings clear and facilitate explanation, in FIG. 1 of the disclosure, each polygon of the dense pattern area A is shown to have a same line width WA, and a pitch PA between each polygon of the dense pattern area A is also shown to be the same. For example, that is, the first polygon I has a line width WA, the second polygon II has a line width WA, the third polygon III has a line width WA, and the fourth polygon IV has a line width WA, and the distance between the first polygon I and the second polygon II is the pitch PA, the distance between the second polygon II and the third polygon III is the pitch PA, and the distance between the third polygon III and the fourth polygon IV is the pitch PA. However, the claimed scope and practical application of the disclosure are not limited thereto.

In addition, the loose pattern area B includes at least one polygon, as shown in FIG. 1. The one such polygon of the loose pattern area B has the line width WB, but the claimed scope and practical application of the disclosure are not limited thereto; moreover, the width WB of the polygons of the loose pattern area B is greater than the width WA of the plurality of polygons of the dense pattern area A.

Therefore, taking the layout layer as a gate layer as an example, the plurality of polygons of the dense pattern area A may include gates; taking the layout layer as a contact layer as an example, the plurality of polygons of the dense pattern area A may include contacts; taking the layout layer as a metal wire layer of the back-end of line process as an example, the plurality of polygons of the dense pattern area A may include the metal wires of the back-end of line process.

Furthermore, the loose pattern area B may include an isolation structure area, such as a shallow trench isolation (STI).

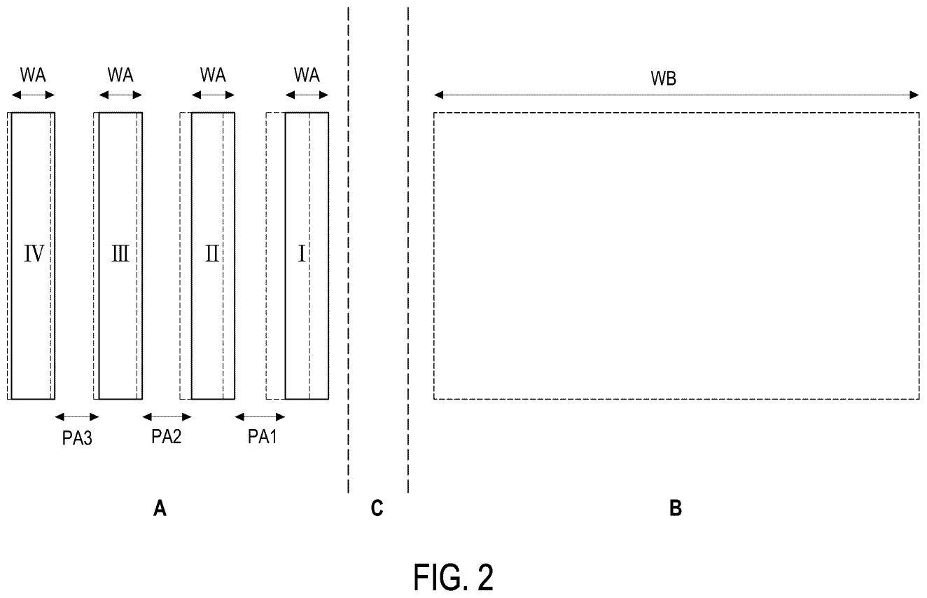

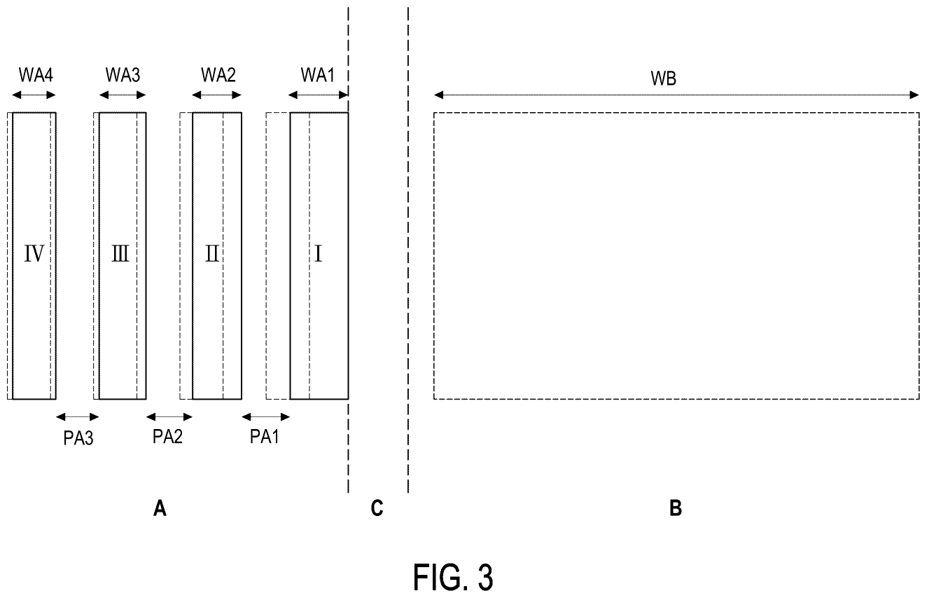

FIG. 2 and FIG. 3 respectively show schematic diagrams of the results after adjustment and correction of the layout pattern of FIG. 1. FIG. 2 is a schematic diagram for adjusting the pitch of the plurality of polygons of the dense pattern area A, while FIG. 3 is a schematic diagram for simultaneously adjusting the pitch and line width of the plurality of polygons of the dense pattern area A; to facilitate comparison, the dotted lines in FIG. 2 and FIG. 3 indicate the positions of the plurality of polygons of the dense pattern area A in FIG. 1.

First, refer to FIG. 2. In the layout design method of the disclosure, it is necessary to first identify the dense pattern area A, the loose pattern area B, and the boundary C of the layout layer; then perform the step of increasing the pitch on N polygons of the plurality of polygons of the dense pattern area A closest to the boundary C, wherein N is an integer. Such a step of increasing the pitch is limited to not affecting a first connection between the layout layer and a lower layer, nor a second connection between the layout layer and an upper layer.

N refers to the number of the polygons of the dense pattern area A where the layout design method of the disclosure will be carried out. As shown in FIG. 2, if N is 4, the layout design method of the disclosure adjusts and corrects the four polygons of the dense pattern area A closest to the boundary C. Please note that this does not mean that the dense pattern area A only includes 4 polygons, but includes more than 4 polygons, and for the 4 polygons of the dense pattern area A closest to the boundary C: the first polygon I, the second polygon II, the third polygon III, and the fourth polygon IV are adjusted and corrected.

If necessary, adjustment and correction may also be performed on, for example, 1, 2, 3, 5, 6, or 7 polygons of the dense pattern area A closest to the boundary C, but the inventive concept of the disclosure is not limited thereto.

The above step of increasing the pitch may include gradually increasing the pitch of the N polygons toward the boundary C. The step of gradually increasing the pitch of the N polygons toward the boundary C includes: gradually increasing the pitch of the N polygons toward the boundary C in arithmetic progression; or gradually increasing the pitch of the N polygons toward the boundary C in geometric progression.

For example, as shown in FIG. 1 and FIG. 2, the distance between the first polygon I and the second polygon II, the distance between the second polygon II and the third polygon III, and the distance between the third polygon III and the fourth polygon IV of the original dense pattern area A are all pitch PA. After adjustment and correction by the layout design method of the disclosure, the distance between the first polygon I and the second polygon II will change from the pitch PA to a pitch PA1, the distance between the second polygon II and the third polygon III will change from the pitch PA to a pitch PA2, and the distance between the third polygon III and the fourth polygon IV will change from the pitch PA to a pitch PA3. The difference between the pitch PA1 and the pitch PA is greater than the difference between the pitch PA2 and the pitch PA, and the difference between the pitch PA2 and the pitch PA is greater than the difference between the pitch PA3 and the pitch PA.

As shown in FIG. 2, take the step of gradually increasing the pitch of the four polygons toward the boundary C in arithmetic progression as an example. For example, if the original pitch PA is 80 nm, then the pitches PA1 to PA3 may be 86 nm, 84 nm, and 82 nm respectively. The magnitude of the increase in pitch is greater toward the boundary C. That is, the pitch PA1 closest to the boundary C has increased by 6 nm, the pitch PA2 second closest to the boundary C has increased by 4 nm, and the pitch PA3 third closest to the boundary C has increased by 2 nm. That is, the closer the pitch is to the boundary C, the greater the magnitude of the increase in pitch. In this example, the difference between the pitches PA1 to PA3 and the original pitch PA increases in arithmetic progression, but the disclosure is not limited thereto and may also increase in geometric progression.

Moreover, the magnitude of the increase in pitch may range from about 0.1% to about 20%, and more preferably, may range from about 1% to about 10%. If the magnitude of the increase in pitch is too small, the correction effect of the disclosure will not be apparent; if the magnitude of the increase in pitch is too large, the layout layer may be misaligned with its lower layer and/or its upper layer, causing problems such as electrical connection failure. Therefore, the step of increasing the pitch described in the disclosure will be limited to not affecting the first connection between the layout layer and the lower layer, nor the second connection between the layout layer and the upper layer, wherein the first connection includes a first electrical connection or a first physical connection, and the second connection includes a second electrical connection or a second physical connection.

Since the plurality of polygons of the dense pattern area A are processed by the layout design method of the disclosure, the magnitude of the increase in pitch is greater closer to the boundary C, that is to say, the closer the N plurality of polygons of the dense pattern area A are to the boundary C, the farther apart they are from each other, which further increases the pattern resolution and reduces abnormal phenomena such as pattern shift, pattern bridge, or pattern broken due to small size or changes in pattern density, and maintains the electrical connections between the layout layer and its upper and lower layers in a normal state.

In addition to the above steps of increasing the pitch for the N plurality of polygons of the dense pattern area A, a similar concept may be used to increase the pitch and width of the N plurality of polygons of the dense pattern area A, as shown in FIG. 3, which will be described below with reference to FIG. 3 with the repetitions of FIG. 2 omitted.

For the N plurality of polygons of the dense pattern area A in the embodiment, the step of increasing the pitch and width is performed. The method of gradually increasing the pitch and line width of the N polygons toward the boundary C is independent of the line width, pitch, arithmetic progressive increase, and geometric progressive increase; more specifically, the method of gradually increasing the pitch and line width of the N polygons toward the boundary C includes: gradually increasing the pitch of the N polygons toward the boundary C in arithmetic progression, or gradually increasing the pitch of the N polygons toward the boundary C in geometric progression; and gradually increasing the line width of the N polygons toward the boundary C in arithmetic progression, or gradually increasing the line width of the N polygons toward the boundary C in geometric progression.

As shown in FIG. 3, in addition to the distance between the first polygon I and the second polygon II, the distance between the second polygon II and the third polygon III, and the distance between the third polygon III and the fourth polygon IV increasing from the pitch PA to PA1, PA2 and PA3 respectively as shown in FIG. 2, the first polygon I, the second polygon II, the third polygon III, and the fourth polygon IV may also be increased from the original line width WA as shown in FIG. 1 to line widths WA1, WA2, WA3 and WA4 respectively.

As mentioned in the above embodiments, in addition to the difference between pitch PA1 and pitch PA being greater than the difference between pitch PA2 and pitch PA, and the difference between pitch PA2 and pitch PA being greater than the difference between pitch PA3 and pitch PA, the difference between the line width WA1 and the line width WA in the embodiment is greater than the difference between line width WA2 and line width WA, and the difference between line width WA2 and line width WA is greater than the difference between line width WA3 and line width WA. That is to say, the closer the N plurality of polygons of the dense pattern area A are to the boundary C, the more the pitch and width are increased to improve the pattern resolution of the exposure.

Each of the magnitude of the increase in pitch and line width may range from about 0.1% to about 20%, and more preferably, may range from about 1% to about 10%. If the magnitude of the increase in pitch and line width is too small, the correction effect of the disclosure will not be apparent; if the magnitude of the increase in pitch and line width is too large, the layout layer may be misaligned with its lower layer and/or its upper layer, causing problems such as electrical connection failure. Therefore, the step of increasing the pitch described in the disclosure will be limited to not affecting the first connection between the layout layer and the lower layer, nor the second connection between the layout layer and the upper layer, wherein the first connection includes a first electrical connection or a first physical connection, and the second connection includes a second electrical connection or a second physical connection.

Since the plurality of polygons of the dense pattern area A are processed by the layout design method of the disclosure, the magnitude of the increase in pitch and line width is greater closer to the boundary C, that is, the closer the N plurality of polygons of the dense pattern area A are to the boundary C, the farther apart they are from each other and become larger in size, which further increases the pattern resolution and reduces abnormal phenomena such as pattern shift, pattern bridge, or pattern broken due to small size or changes in pattern density, and maintains the electrical connections between the layout layer and its upper and lower layers in a normal state.

Although the disclosure has been described with reference to the embodiments above, the embodiments are not intended to limit the disclosure. Any person skilled in the art can make some changes and modifications without departing from the spirit and scope of the disclosure. Therefore, the scope of the disclosure will be defined in the appended claims.

What is claimed is:

1. A layout design method, comprising:
identifying a dense pattern area, a loose pattern area, and a boundary of a layout layer, wherein:
the loose pattern area is adjacent to the dense pattern area,
the boundary is located between the dense pattern area and the loose pattern area,
the dense pattern area comprises a plurality of polygons, and
the loose pattern area comprises at least one polygon; and
performing a step of increasing a pitch on N polygons of the plurality of polygons of the dense pattern area closest to the boundary, wherein N is an integer, and the step of increasing the pitch is limited to not affecting a first connection between the layout layer and a lower layer, nor a second connection between the layout layer and an upper layer.

2. The layout design method according to claim 1, wherein the step of increasing the pitch comprises gradually increasing the pitch of the N polygons toward the boundary.

3. The layout design method according to claim 2, wherein gradually increasing the pitch of the N polygons toward the boundary comprises:
gradually increasing the pitch of the N polygons toward the boundary in arithmetic progression; or
gradually increasing the pitch of the N polygons toward the boundary in geometric progression.

4. The layout design method according to claim 1, wherein N is 1 to 7.

5. The layout design method according to claim 1, wherein the step of increasing the pitch comprises increasing the pitch of the N polygons by 0.1% to 20%.

6. The layout design method according to claim 1, wherein the layout layer comprises a gate layer, a contact layer, or a metal wire layer of a back-end of line process.

7. The layout design method according to claim 1, wherein the plurality of polygons of the dense pattern area comprise gates, contacts, or metal wires of a back-end of line process.

8. The layout design method according to claim 1, wherein a width of the at least one polygon of the loose pattern area is greater than a width of the plurality of polygons of the dense pattern area.

9. The layout design method according to claim 1, wherein the loose pattern area comprises an isolation structure area, and the isolation structure area comprises a shallow trench isolation (STI).

10. The layout design method according to claim 1, wherein the first connection comprises a first electrical connection or a first physical connection, and the second connection comprises a second electrical connection or a second physical connection.

11. A layout design method, comprising:
identifying a dense pattern area, a loose pattern area, and a boundary of a layout layer, wherein:
the loose pattern area is adjacent to the dense pattern area,
the boundary is located between the dense pattern area and the loose pattern area,
the dense pattern area comprises a plurality of polygons, and
the loose pattern area comprises at least one polygon; and
performing a step of increasing a pitch and a line width on N polygons of the plurality of polygons of the dense pattern area closest to the boundary, wherein N is an integer, and the step of increasing the pitch and the line width is limited to not affecting a first connection between the layout layer and a lower layer, nor a second connection between the layout layer and an upper layer.

12. The layout design method according to claim 11, wherein the step of increasing the pitch and the line width comprises gradually increasing the pitch and the line width of the N polygons toward the boundary.

13. The layout design method according to claim 12, wherein gradually increasing the pitch and the line width of the N polygons toward the boundary comprises:
gradually increasing the pitch of the N polygons toward the boundary in arithmetic progression, or gradually increasing the pitch of the N polygons toward the boundary in geometric progression; and
gradually increasing the line width of the N polygons toward the boundary in arithmetic progression, or gradually increasing the line width of the N polygons toward the boundary in geometric progression.

14. The layout design method according to claim 11, wherein N is 1 to 7.

15. The layout design method according to claim 11, wherein the step of increasing the pitch and the line width comprises:
increasing the pitch of the N polygons by 0.1% to 20%; and
increasing the line width of the N polygons by 0.1% to 20%.

16. The layout design method according to claim 11, wherein the layout layer comprises a gate layer, a contact layer, or a metal wire layer of a back-end of line process.

17. The layout design method according to claim 11, wherein the plurality of polygons of the dense pattern area comprise gates, contacts, or metal wires of a back-end of line process.

18. The layout design method according to claim 11, wherein a width of the at least one polygon of the loose pattern area is greater than a width of the plurality of polygons of the dense pattern area.

19. The layout design method according to claim 11, wherein the loose pattern area comprises an isolation structure area, and the isolation structure area comprises a shallow trench isolation (STI).

20. The layout design method according to claim 11, wherein the first connection comprises a first electrical connection or a first physical connection, and the second connection comprises a second electrical connection or a second physical connection.
